(19) United States
(12) Patent Application Publication
(10) Pub. No.: US 2026/0059772 A1
(43) Pub. Date: Feb. 26, 2026

(54) NOVEL SWITCHING INDUCTOR

(71) Applicants: Applied Materials, Inc., Santa Clara, CA (US); Institute of Microelectronics, Singapore (SG)

(72) Inventors: Mudit Sunilkumar KHASGIWALA, Milpitas, CA (US); Meghna Maheshkumar PATEL, Navsari (IN); Kunal GHOSH, Bengaluru (IN); Sachin Jayant PATIL, Bengaluru (IN); Lim Teck GUAN, Singapore (SG); Mihai Dragos ROTARU, Singapore (SG); Chui King JIEN, Singapore (SG); Vempati Srinivasa RAO, Singapore (SG)

(73) Assignees: Applied Materials, Inc., Santa Clara, CA (US); Agency for Science, Technology and Research, Singapore (SG)

(21) Appl. No.: 18/812,074

(22) Filed: Aug. 22, 2024

(51) Int. Cl. H01L 23/48; H01L 23/522; H01L 23/532

(52) U.S. Cl. CPC H10D 1/20; H01L 23/481; H01L 23/5227; H01L 23/53228

(57) ABSTRACT

An embedded inductor may include a substrate. The inductor may include a first layer of magnetic film, disposed on a first side of the substrate. The inductor may include a second layer of magnetic film, disposed on a second side of the substrate. The inductor may include a dielectric layer disposed over each of the first and second layers of magnetic film may include. The inductor may include a first redistribution layer formed over the dielectric layer. The inductor may include a second redistribution layer a formed over the dielectric layer. The inductor may include two or more through-substrate vias (TSVs) extending through the dielectric layer and the substrate from the first redistribution layer to the second redistribution layer.

### TECHNICAL FIELD

The present technology relates to semiconductor systems, processes, and equipment. More specifically, the present technology relates to inductors and methods of manufacturing thereof.

### BACKGROUND

Modern electronic devices require discrete inductors to perform many functions. As the performance requirements of the electronic devices increase, so does the need for inductors that can provide a high inductance for the space and inductor takes within the device. Furthermore, the inductors also need to be able to provide better performance in handling currents at the power levels and/or frequencies used in the electronic devices.

### BRIEF SUMMARY

An embedded inductor may include a substrate. The inductor may include a first layer of magnetic film, disposed on a first side of the substrate. The inductor may include a second layer of magnetic film, disposed on a second side of the substrate. The inductor may include a dielectric layer disposed over each of the first and second layers of magnetic film may include. The inductor may include a first redistribution layer formed over the dielectric layer. The inductor may include a second redistribution layer a formed over the dielectric layer. The inductor may include two or more through-substrate vias (TSVs) extending through the dielectric layer and the substrate from the first redistribution layer to the second redistribution layer.

In some embodiments, the first and second layers of magnetic film may include cadmium zinc telluride (CZT). The dielectric layer may include at least one of polyimide, zirconium, silica, or hydrogensilsesquioxanes. The two or more TSVs form windings of the embedded inductor. The first and second layers of magnetic film may include a thickness within a range of about 1 μm to about 3 μm, inclusive. The redistribution layer may include copper. The two or more TSVs may include copper.

A core embedded inductor may include a substrate. The inductor may include a first layer of magnetic film, disposed on a first side of the substrate. The inductor may include a second layer of magnetic film, disposed on a second side of the substrate. The inductor may include a dielectric layer disposed over each of the first and second layers of magnetic film. The inductor may include a first redistribution layer formed over the dielectric layer on the first surface of the substrate. The inductor may include a second redistribution layer formed over the dielectric layer on the second surface of the substrate. The inductor may include two or more TSVs extending through the dielectric layer and the substrate from the first redistribution layer to the second redistribution layer. The inductor may include a second dielectric layer disposed over each of the first and second redistribution layers. The inductor may include a third layer of magnetic film disposed on the second dielectric layer over at least a portion of the first redistribution layer. The inductor may include a fourth layer of magnetic film disposed on the second dielectric layer over at least a portion of the second redistribution layer.

In some embodiments, the dual core embedded inductor where the first and second redistribution layers extend beyond the second dielectric layer. The embedded inductor may be an integrated voltage regulator. The embedded inductor may be a switching inductor. The two or more TSVs may form a winding of a solenoidal inductor. The first and second layers of magnetic film may be formed from a material with a ferromagnetic resonance frequency of about 1 GHz to about 2 GHz, inclusive.

A method of forming an inductor may include forming two or more TSVs in a substrate such that the TSVs reaches the first surface of the substrate. The method may include forming a first layer of magnetic film on the first surface of the substrate between at least two of the TSVs. The method may include forming a first dielectric layer on the first surface of the substrate and the first layer of magnetic film. The method may include forming a first metal layer on the first dielectric layer, such that the metal vias extend through the first dielectric layer. The method may include extending the TSVs such that the TSVs reach a second surface of the substrate, opposite the first surface. The method may include forming a second layer of magnetic film on the second surface of the substrate and between at least two of the TSVs. The method may include forming a second dielectric layer on the second surface of the substrate and the second layer of magnetic film. The method may include forming a second metal layer on the second dielectric layer.

In some embodiments, the method may include forming a third dielectric layer on the first metal layer. The method may also include forming a third layer of magnetic film on the third dielectric layer. The method may also include forming a fourth dielectric layer on the second metal layer. The method may also include and forming a fourth layer of magnetic film on the second dielectric layer.

In some embodiments, the first metal layer and the second metal layer may include a redistribution layer. The two or more TSVs may be formed at least in part using an etching process. The first and second metal layers may be formed via a sputtering process. The substrate may include silicon. The first, second, third, and fourth layers of magnetic film are formed using a deposition process.

### BRIEF DESCRIPTION OF THE DRAWINGS

FIG. 1 illustrates a flowchart of a method for forming an embedded inductor, according to certain embodiments.

FIG. 2 illustrates a flowchart of a method for forming a dual core embedded inductor, according to certain embodiments.

FIGS. 3A-3I illustrate a process flow of the method for forming an embedded inductor, according to certain embodiments.

FIGS. 3J-3K for forming an embedded dual core inductor, according to certain embodiments.

FIG. 4 illustrates an exemplary computer system, in which various embodiments may be implemented.

### DETAILED DESCRIPTION

Voltage regulators with integrated magnetics may be an important component of current and future electronic devices for high-performance computing and communication systems. These are integrated with various system hardware integration architectures such as System on a Chip (SOC) technologies, advanced multichip, multichiplet or heterogeneous-integrated packages, and other such devices. Some of all of these devices may require high frequency switching regulators for high efficiency and granular power delivery where the power supply is optimized for each domain within an integrated circuit (IC). Commonly available inductors may experience current ripple and/or direct current (DC) losses (e.g., via eddy current losses at or near operating frequencies of such device. An integrated inductor, included in such a device may reduce the current ripple and/or DC losses by utilizing multiphase switching close to the active circuits. One way to increase the inductance of an integrated inductor is to increase the number of windings (generally copper) included in the inductor. As the number of windings increases, however, the resistance also increases. Furthermore, the amount of current ripple or drift may also increase. Minimizing the number of copper windings in an integrated inductor may address some of these issues. Furthermore, power source components like IVR's (Integrated Voltage Regulators) and its integrated passive devices (IPDs) may be placed as close as possible to the load to reduce the current drop and have optimal power delivery network (PDN) response. The IVRs and IPDs may therefore be integrated into the PDN subsystems in order to place the devices as close as possible to the loads.

One device that may be integrated into such a package may be a high current switching inductor. An IVR may have a switching frequency in 100's of MHz. Miniaturization of a switching inductor may enable miniaturization of the in a package and/or on chip level integration. However, the miniaturization of the PDN and reduction in the size of the switching inductor(s) may present other challenges such as higher eddy current losses which impact overall system efficiency. One solution may an embedded (or integrated) switching inductor with a high inductive reactance and a low direct current (DC) ripple. An integrated inductors may include a substrate, with layers of magnetic film on opposite sides of the substrate. A dielectric layer may be disposed over the substrate and or layers of magnetic film. Metallic vias extend through the dielectric layer and the substrate, forming a through substrate via (TSV). Metal layers may then be disposed on the dielectric layer and be electrically connected to the TSV(s). The metal layers may then be redistribution layers, and the TSVs windings of the integrated inductor. The layers of magnetic film may be a magnetic core, raising the inductive reactance of the integrated inductor. Because the inductive reactance may be raised by the layers of magnetic film, the number of windings (i.e., TSVs) may be reduced, improving the DC ripple effects of the integrated inductor. Thus, the integrated inductor may have a smaller form factor than the current technology while offering improved performance over conventional IVRs (and/or PDNs).

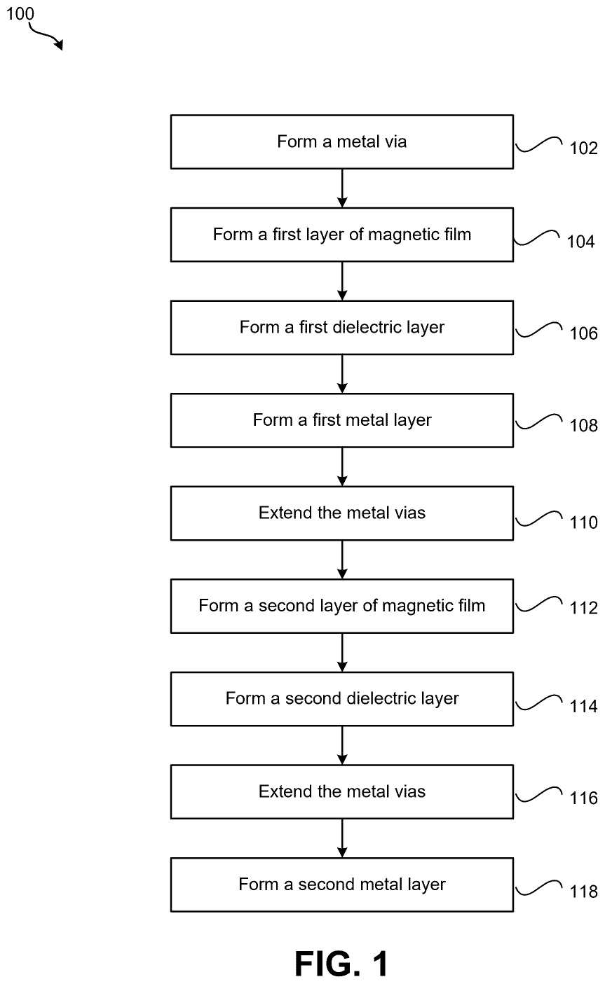

FIG. 1 illustrates a flowchart of a method 100 for forming an embedded inductor, according to certain embodiments. Steps of the method 100 may be performed in a different order than is shown in FIG. 1 and/or combined with other steps of the method 100. In some embodiments, some of the steps of the method 100 may be skipped altogether. The method 100 may be performed using a semiconductor processing chamber, controlled at least in part by a computing system. The computing system may cause components of the semiconductor processing chamber to perform some or all of the method 100.

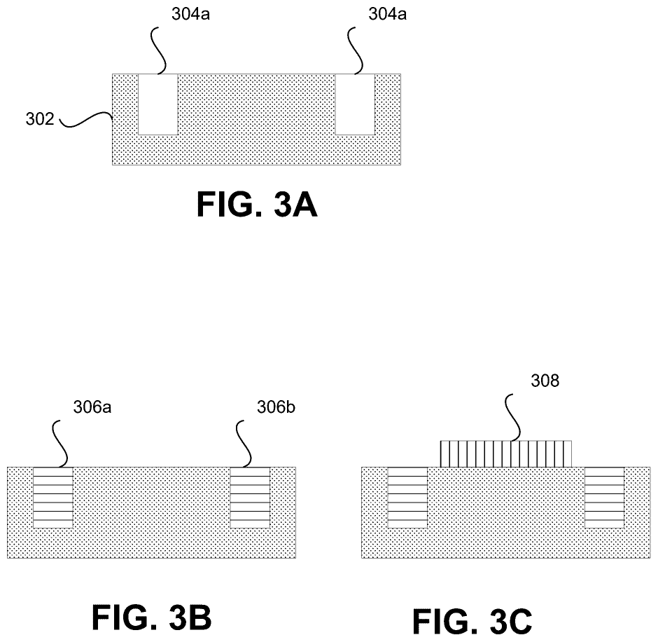

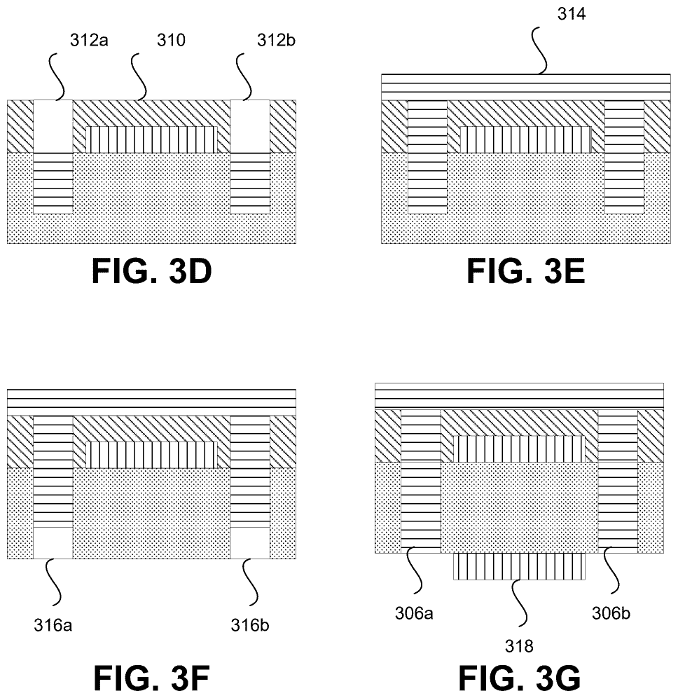

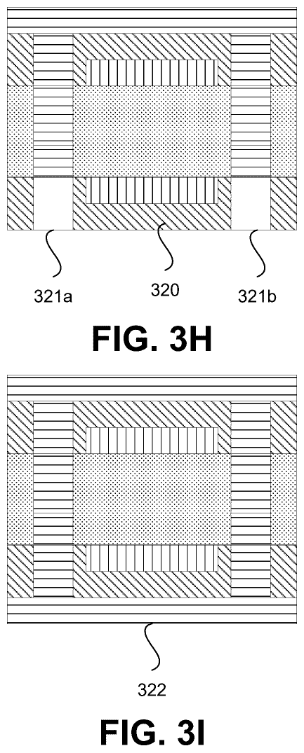

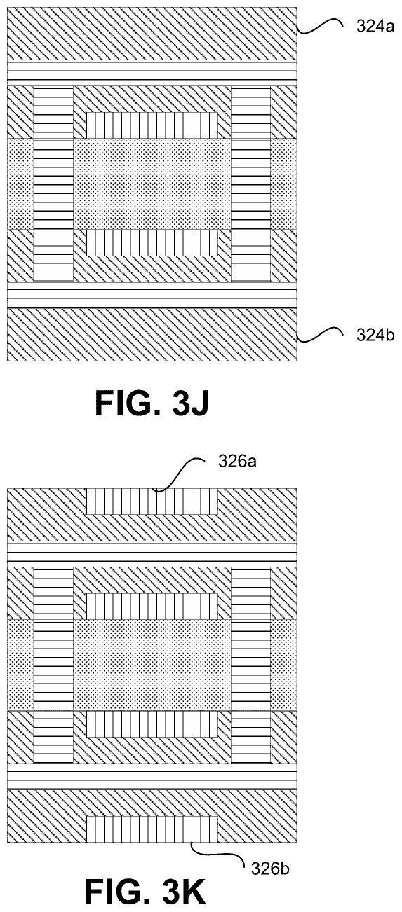

At step 102, the method 100 may include forming two or more through-substrate vias (TSVs) in a substrate. As shown in FIG. 3A, cavities 304a-b may extend from a first surface of a substrate 302 to some point within the substrate 302. The substrate 302 may include silicon, polyimide, glass, liquid crystal polymer, fluoropolymer, Molypermalloy powder cores, High Flux, kool Mu®/Sendust, or other suitable substrate materials. The substrate 302 may include a thickness of about 1 mm to about 20 mm. The cavities 304a-b may be formed using a laser, mechanical drill, or formed via an etching and/or ablation process. The cavities 304a-b may include a diameter of about 10 μm, about 15 μm, about 20 μm, about 25 μm, about 30 μm, about 40 μm, about 50 μm, about 60 μm, and/or about 70 μm. In some embodiments, all of the cavities 304a-b include the same diameter. In other embodiments, the cavities 304a-b may include different diameters. The cavities 304a-b may then be at least partially filled with metal to form through substrate vias (TSVs) 306a-b, as seen in FIG. 3B. The TSVs 306a-b may include copper, silver, nickel, and/or any other suitable metal. Although only two TSVs 306a-b are shown, it should be understood that any number of metal vias may be present.

At step 104, the method 100 may include forming a first layer of magnetic film 308 on the first surface of the substrate 302 between at least two of the TSVs 306a-b, as shown in FIG. 3C. The first layer of magnetic film 308 may be deposited to a thickness of about 10 μm, about 15 μm, about 20 μm, about 25 μm, or about 30 μm. The first layer of magnetic film 308 ferromagnetic resonance frequency of about 1 GHz to about 2 GHz. The first layer of magnetic film 308 may include Cadmium Zinc Telluride (CZT), nickel, iron, cobalt, zirconium, tantalum, and/or any other suitable material. The first layer of magnetic film 308 may include a single material or may include combinations and alloys of any or all of the aforementioned materials. In some embodiments, the first layer of magnetic film 308 may be formed by sputtering one or more materials on the substrate 302. In other embodiments, the first layer of magnetic film 308 may be formed by other physical vapor deposition (PVD) techniques such as e-beam evaporation, atomic layer deposition (ALD), or any other type of deposition. In some embodiments, multiple layers of magnetic film may deposited via sputtering. The multiple layers of magnetic film may been interspersed with a thin oxide of a material such as zirconium, silica or others. In some embodiments, a single oxide layer may be formed on the first layer of magnetic film 308. The single oxide layer may serve as a dielectric and aid in isolating the first layer of magnetic film 308 from other layers of the integrated inductor.

At step 106, the method 100 may include forming a first dielectric layer 310 on the first surface of the substrate 302 and the first layer of magnetic film 308, as shown in FIG. 3D. The first dielectric layer 310 may be patterned to include cavities 312a-b corresponding to the TSVs 306a-b. The first dielectric layer 310 may include as epoxy, polyimide, silicones, hydrogensilsesquioxanes, and/or siloxanes. The first dielectric layer 310 may be formed to a thickness of about 5μm, about 10 μm, about 15 μm, or about 20 μm.

In some embodiments, the first dielectric layer 310 may include one or more polymers or other suitable materials. The first dielectric layer 310 may include a dielectric material such as polypropylene, cyclic transparent optical fluoropolymer (CYTOP), polypropylene-co-1-butene, or other suitable polymers and/or materials. The first dielectric layer 310 may planarize the first layer of magnetic film 308. For example, forming the first layer of magnetic film 308 may create imperfections or an uneven surface. The first dielectric layer 310 may be formed such that the imperfections are filled in and/or such that a surface of the first dielectric layer 310 is even.

At step 108, the method 100 may include forming a first metal layer 314 on at least a portion of the first dielectric layer 310, as shown in FIG. 3E. The first metal layer 314 may include copper, silver, nickel, and/or any other suitable metal. The first metal layer 314 may be formed via PVD, ALD, sputtering, and/or other suitable deposition processes. The first metal layer 314 may additionally or alternatively be formed via an electroplating process. For example, the first metal layer 314 may be formed by depositing a metal seeding layer via PVD, then electroplating the first metal layer 314 on the metal seeding layer. The first metal layer 314 may be formed to a thickness of about 5 μm, about 10 μm, about 15 μm, about 20 μm, or about 30 μm.

The first metal layer 314 may be formed such that the cavities 312a-b are completely filled. Thus, the cavities 312a-b may extend the TSVs 306a-b such that the TSVs 306a-b extend through the first dielectric layer 310 and are in contact with the first metal layer 304. The TSVs 306a-b may at least partially form windings (e.g., a copper winding) surrounding a magnetic core (e.g., the substrate 302 and the first layer of magnetic film 308). The first metal layer 314 may be a redistribution layer, enabling the embedded inductor to be integrated into a package or other on-chip system.

At step 110, the method 100 may include extending the TSVs 306a-b such that the TSVs 306a-b reach a second surface of the substrate 302. To extend the TSVs 306a-b, cavities 316a-b may be formed in the substrate 302 as shown in FIG. 3F. The cavities 316a-b may be formed using a laser, mechanical drill, or formed via an etching and/or ablation process. The cavities 316a-b may include a diameter of about 10 μm, about 15 μm, about 20 μm, about 25 μm, about 30 μm, about 40 μm, about 50 μm, about 60 μm, and/or about 70 μm. In some embodiments, all of the cavities 316a-b include the same diameter. In other embodiments, the cavities 316a-b may include different diameters. The cavities 316a-b may be at least partially filled with metal (e.g., copper, silver, etc.) or may be left empty at this step. In some embodiments, the substrate 302 may be patterned to enable growth of the metal used to fill the cavities 316a-b to extend the TSVs 306a-b.

At step 112, the method 100 may include forming a second layer of magnetic film 318 on the second surface of the substrate 302 and between at least two of the TSVs 306a-b, as shown in FIG. 3G. The second layer of magnetic film 318 may be deposited to a thickness of about 10 μm, about 15 μm, about 20 μm, about 25 μm, or about 30 μm. The second layer of magnetic film 318 ferromagnetic resonance frequency of about 1 GHz to about 2 GHz The second layer of magnetic film 318 may include Cadmium Zinc Telluride (CZT), nickel, iron, cobalt, zirconium, tantalum, and/or any other suitable material. The second layer of magnetic film 318 may include a single material or may include combinations and alloys of any or all of the aforementioned materials. In some embodiments, the second layer of magnetic film 318 may be formed by sputtering one or more materials on the substrate 302. In other embodiments, the second layer of magnetic film 318 may be formed by other physical vapor deposition (PVD) techniques such as e-beam evaporation, atomic layer deposition (ALD), or any other type of deposition. In some embodiments, multiple layers of magnetic film may deposited via sputtering. The multiple layers of magnetic film may been interspersed with a thin oxide of a material such as zirconium, silica or others. In some embodiments, a single oxide layer may be formed on the second layer of magnetic film 318. The single oxide layer may serve as a dielectric and aid in isolating the second layer of magnetic film 318 from other layers of the integrated inductor.

At step 114, the method 100 may include a second dielectric layer 320 on the second surface of the substrate 302 and the second layer of magnetic film 318, as shown in FIG. 3H. The second dielectric layer 320 may be patterned to include cavities 321a-b corresponding to the TSVs 306a-b. In some embodiments, the cavities 321a-b may be formed by formed using a laser, mechanical drill, or formed via an etching and/or ablation process. The second dielectric layer 320 may include as epoxy, polyimide, silicones, and/or siloxanes. The second dielectric layer 320 may be formed to a thickness of about 5 μm, about 10 μm, about 15 μm, or about 20 μm.

In some embodiments, the second dielectric layer 320 may include one or more polymers or other suitable materials. The second dielectric layer 320 may include a dielectric material such as polypropylene, cyclic transparent optical fluoropolymer (CYTOP), polypropylene-co-1-butene, or other suitable polymers and/or materials. The second dielectric layer 320 may planarize the second layer of magnetic film 318. For example, forming the second layer of magnetic film 308 may create imperfections or an uneven surface. The second dielectric layer 320 may be formed such that the imperfections are filled in and/or such that a surface of the second dielectric layer 320 is even.

At step 116, the method 100 may include forming a second metal layer 322 on the second dielectric layer 320, as shown in FIG. 3I. The second metal layer 322 may include copper, silver, nickel, and/or any other suitable metal. The second metal layer 322 may be formed via PVD, ALD, sputtering, and/or other suitable deposition processes. The second metal layer 322 may additionally or alternatively be formed via an electroplating process. For example, the second metal layer 322 may be formed by depositing a metal seeding layer via PVD, then electroplating the second metal layer 322 on the metal seeding layer. The second metal layer 322 may be formed to a thickness of about 5 μm, about 10 μm, about 15 μm, about 20 μm, or about 30 μm.

The second metal layer 322 may be formed such that the cavities 321a-b are completely filled. Thus, the cavities 321a-b may extend the TSVs 306a-b such that the TSVs 306a-b extend through the second dielectric layer 320 and are in contact with the second metal layer 322. The TSVs 306a-b may form windings (e.g., a copper winding) surrounding a magnetic core (e.g., the substrate 302, the first layer of magnetic film 308 and the second layer of magnetic film 318). The second metal layer 322 may be a redistribution layer, enabling the embedded inductor to be integrated into a package or other on-chip system.

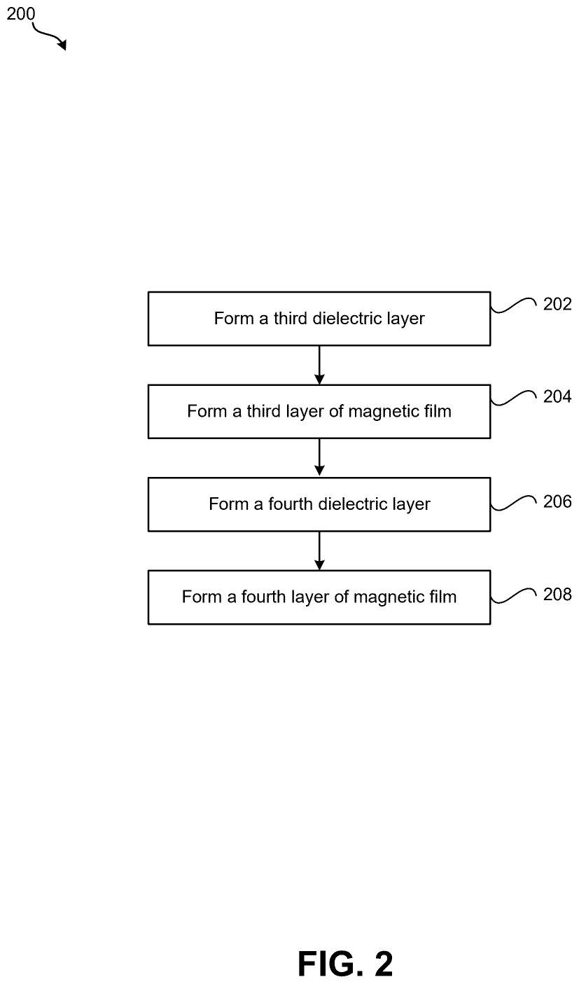

FIG. 2 illustrates a flowchart of a method 200 for forming a dual core embedded inductor, according to certain embodiments. Steps of the method 200 may be performed in a different order than is shown in FIG. 2 and/or combined with other steps of the method 200. In some embodiments, some of the steps of the method 200 may be skipped altogether. The method 200 may be combined with the method 100 in FIG. 1 or may be performed on a pre-manufactured device. The method 200 may be performed using a semiconductor processing chamber, controlled at least in part by a computing system. The computing system may cause components of the semiconductor processing chamber to perform some or all of the method 200.

At step 202, the method 200 may include forming a third dielectric layer 324a on the first metal layer 314, as shown in FIG. 3J. The third dielectric layer 324a may include as epoxy, polyimide, silicones, and/or siloxanes. The third dielectric layer 324a may be formed to a thickness of about 5 μm, about 10 μm, about 15 μm, or about 20 μm.

In some embodiments, the third dielectric layer 324a may include one or more polymers or other suitable materials. The third dielectric layer 324a may include a dielectric material such as polypropylene, cyclic transparent optical fluoropolymer (CYTOP), polypropylene-co-1-butene, or other suitable polymers and/or materials.

At step 204, the method 200 may include forming a fourth dielectric layer 324b on the second metal layer 322, as shown in FIG. 3J. The fourth dielectric layer 324b may include as epoxy, polyimide, silicones, and/or siloxanes. The fourth dielectric layer 324b may be formed to a thickness of about 5 μm, about 10 μm, about 15 μm, or about 20 μm.

In some embodiments, the fourth dielectric layer 324b may include one or more polymers or other suitable materials. The fourth dielectric layer 324b may include a dielectric material such as polypropylene, cyclic transparent optical fluoropolymer (CYTOP), polypropylene-co-1-butene, or other suitable polymers and/or materials.

At step 206, the method 200 may include forming a third layer of magnetic film 326a on the third dielectric layer 324a, as shown in FIG. 3K. The third layer of magnetic film 326a may be deposited to a thickness of about 10 μm, about 15 μm, about 20 μm, about 25 μm, or about 30 μm. The third layer of magnetic film 326a may include CZT, iron, cobalt, zirconium, tantalum, and/or any other suitable material. The third layer of magnetic film 326a may include a single material or may include combinations and alloys of any or all of the aforementioned materials. In some embodiments, the third layer of magnetic film 326a may be formed by sputtering one or more materials on the substrate 302. In other embodiments, the third layer of magnetic film 326a may be formed by other physical vapor deposition (PVD) techniques such as e-beam evaporation, atomic layer deposition (ALD), or any other type of deposition. In some embodiments, multiple layers of magnetic film may deposited via sputtering. The multiple layers of magnetic film may been interspersed with a thin oxide of a material such as zirconium, silica or others. In some embodiments, a single oxide layer may be formed on the third layer of magnetic film 326a. The single oxide layer may serve as a dielectric and aid in isolating the third layer of magnetic film 326a from other layers of the integrated inductor.

At step 208, the method 200 may include forming a fourth layer of magnetic film 326b on the fourth dielectric layer 324b, as shown in FIG. 3K. The fourth layer of magnetic film 326b may be deposited to a thickness of about 10 μm, about 15 μm, about 20 μm, about 25 μm, or about 30 μm. The fourth layer of magnetic film 326b may include CZT, nickel, iron, cobalt, zirconium, tantalum, and/or any other suitable material. The fourth layer of magnetic film 326b may include a single material or may include combinations and alloys of any or all of the aforementioned materials. In some embodiments, the fourth layer of magnetic film 326b may be formed by sputtering one or more materials on the substrate 302. In other embodiments, the fourth layer of magnetic film 326b may be formed by other physical vapor deposition (PVD) techniques such as e-beam evaporation, atomic layer deposition (ALD), or any other type of deposition. In some embodiments, multiple layers of magnetic film may deposited via sputtering. The multiple layers of magnetic film may been interspersed with a thin oxide of a material such as zirconium, silica or others. In some embodiments, a single oxide layer may be formed on the fourth layer of magnetic film 326b. The single oxide layer may serve as a dielectric and aid in isolating the fourth layer of magnetic film 326b from other layers of the integrated inductor.

The embedded inductor shown in FIG. 3K and formed using the method 200 may have an increased inductive reactance as compared to conventional inductors. The third layer of magnetic film 326a and the fourth layer of magnetic film 326b may increase the performance of the magnetic core (e.g., the first and second layers of magnetic film 308 and 318), allowing for greater inductive performance for a given number of windings in the embedded inductor. The embedded inductor in FIG. 3K may be considered a “dual core” inductor where a second magnetic core (e.g., the third and fourth dielectric layers and third and fourth layers of magnetic film) is disposed over the windings of a solenoidal inductor. Thus, the embedded inductor may provide for a reduction in magnetic core loss with better DC ripple performance over the current technology. In other words, the embedded inductors described herein may be able to operate at high currents and/or frequencies. The higher current operation of the embedded inductor may store more energy. When that energy is required (e.g., an IVR application) the embedded inductor may provide higher currents at a constant voltage than the present technology. This means that the embedded inductor may smooth out fluctuations in the input voltage or load, providing a more stable output voltage.

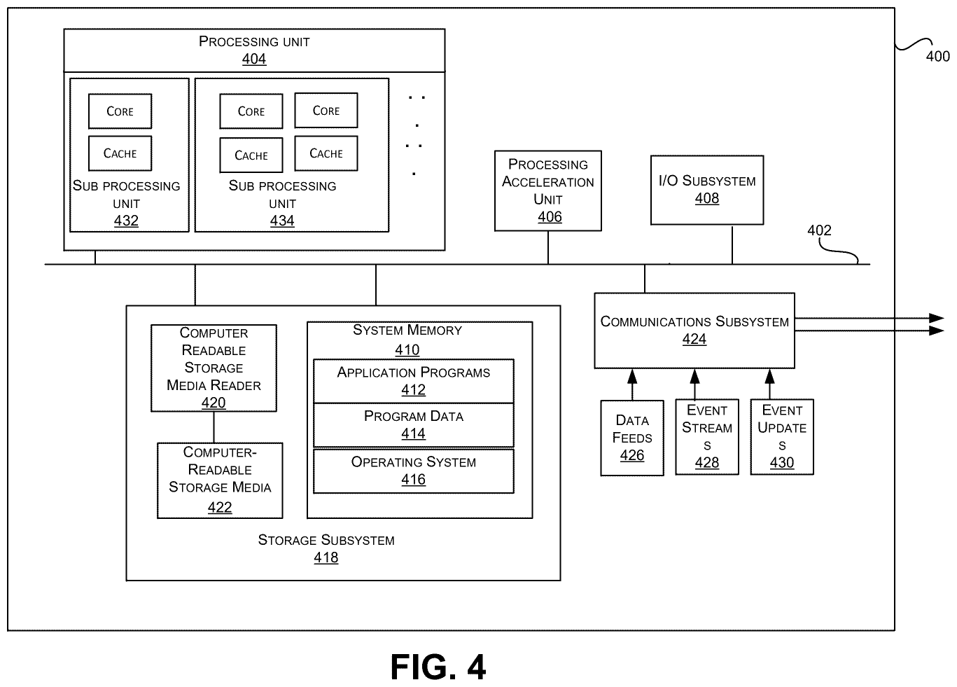

FIG. 4 illustrates an exemplary computer system 400, in which various embodiments may be implemented. The system 400 may be used to implement any of the methods described herein. For example, the system 400 may at least partially control a semiconductor processing chamber and related systems to perform the methods 100 and/or 200. As shown in the figure, computer system 400 includes a processing unit 404 that communicates with a number of peripheral subsystems via a bus subsystem 402. These peripheral subsystems may include a processing acceleration unit 406, an I/O subsystem 408, a storage subsystem 418 and a communications subsystem 424. Storage subsystem 418 includes tangible computer-readable storage media 422 and a system memory 410.

Bus subsystem 402 provides a mechanism for letting the various components and subsystems of computer system 400 communicate with each other as intended. Although bus subsystem 402 is shown schematically as a single bus, alternative embodiments of the bus subsystem may utilize multiple buses. Bus subsystem 402 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 404, which can be implemented as one or more integrated circuits (e.g., a conventional microprocessor or microcontroller), controls the operation of computer system 400. One or more processors may be included in processing unit 404. These processors may include single core or multicore processors. In certain embodiments, processing unit 404 may be implemented as one or more independent processing units 432 and/or 434 with single or multicore processors included in each processing unit. In other embodiments, processing unit 404 may also be implemented as a quad-core processing unit formed by integrating two dual-core processors into a single chip.

In various embodiments, processing unit 404 can execute a variety of programs in response to program code and can maintain multiple concurrently executing programs or processes. At any given time, some or all of the program code to be executed can be resident in processor(s) 404 and/or in storage subsystem 418. Through suitable programming, processor(s) 404 can provide various functionalities described above. Computer system 400 may additionally include a processing acceleration unit 406, which can include a digital signal processor (DSP), a special-purpose processor, and/or the like.

I/O subsystem 408 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices. User interface input devices may include, for example, motion sensing and/or gesture recognition devices that enables users to control and interact with an input device through a natural user interface using gestures and spoken commands. Additionally, user interface input devices may include voice recognition sensing devices that enable users to interact with voice recognition systems through voice commands.

User interface input devices may also include, without limitation, three dimensional (3D) mice, joysticks or pointing sticks, gamepads and graphic tablets, and audio/visual devices such as speakers, digital cameras, digital camcorders, portable media players, webcams, image scanners, fingerprint scanners, barcode reader, 3D scanners, 3D printers, laser rangefinders, and eye gaze tracking devices. Additionally, user interface input devices may include, for example, medical imaging input devices such as computed tomography, magnetic resonance imaging, position emission tomography, medical ultrasonography devices. User interface input devices may also include, for example, audio input devices such as MIDI keyboards, digital musical instruments and the like.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 400 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 400 may comprise a storage subsystem 418 that comprises software elements, shown as being currently located within a system memory 410. System memory 410 may store program instructions that are loadable and executable on processing unit 404, as well as data generated during the execution of these programs.

Depending on the configuration and type of computer system 400, system memory 410 may be volatile (such as random access memory (RAM)) and/or non-volatile (such as read-only memory (ROM), flash memory, etc.). The RAM typically contains data and/or program modules that are immediately accessible to and/or presently being operated and executed by processing unit 404. In some implementations, system memory 410 may include multiple different types of memory, such as static random access memory (SRAM) or dynamic random access memory (DRAM). In some implementations, a basic input/output system (BIOS), containing the basic routines that help to transfer information between elements within computer system 400, such as during start-up, may typically be stored in the ROM. By way of example, and not limitation, system memory 410 also illustrates application programs 412, which may include client applications, Web browsers, mid-tier applications, relational database management systems (RDBMS), etc., program data 414, and an operating system 416.

Storage subsystem 418 may also provide a tangible computer-readable storage medium for storing the basic programming and data constructs that provide the functionality of some embodiments. Software (programs, code modules, instructions) that when executed by a processor provide the functionality described above may be stored in storage subsystem 418. These software modules or instructions may be executed by processing unit 404. Storage subsystem 418 may also provide a repository for storing data used in accordance with some embodiments.

Storage subsystem 400 may also include a computer-readable storage media reader 420 that can further be connected to computer-readable storage media 422. Together and, optionally, in combination with system memory 410, computer-readable storage media 422 may comprehensively represent remote, local, fixed, and/or removable storage devices plus storage media for temporarily and/or more permanently containing, storing, transmitting, and retrieving computer-readable information.

Computer-readable storage media 422 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 400.

By way of example, computer-readable storage media 422 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD or other optical media. Computer-readable storage media 422 may include, but is not limited to, flash memory cards, universal serial bus (USB) flash drives, secure digital (SD) cards, DVD disks, digital video tape, and the like. Computer-readable storage media 422 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 400.

Communications subsystem 424 provides an interface to other computer systems and networks. Communications subsystem 424 serves as an interface for receiving data from and transmitting data to other systems from computer system 400. For example, communications subsystem 424 may enable computer system 400 to connect to one or more devices via the Internet. In some embodiments communications subsystem 424 can include radio frequency (RF) transceiver components for accessing wireless voice and/or data networks (e.g., using cellular telephone technology, advanced data network technology, such as 3G, 4G, 4G, or EDGE (enhanced data rates for global evolution), WiFi (IEEE 802.4 family standards, or other mobile communication technologies, or any combination thereof), global positioning system (GPS) receiver components, and/or other components. In some embodiments communications subsystem 424 can provide wired network connectivity (e.g., Ethernet) in addition to or instead of a wireless interface.

In some embodiments, communications subsystem 424 may also receive input communication in the form of structured and/or unstructured data feeds 426, event streams 428, event updates 430, and the like on behalf of one or more users who may use computer system 400.

By way of example, communications subsystem 424 may be configured to receive data feeds 426 in real-time from users of social networks and/or other communication services, web feeds such as Rich Site Summary (RSS) feeds, and/or real-time updates from one or more third party information sources.

Additionally, communications subsystem 424 may also be configured to receive data in the form of continuous data streams, which may include event streams 428 of real-time events and/or event updates 430, that may be continuous or unbounded in nature with no explicit end. Examples of applications that generate continuous data may include, for example, sensor data applications, financial tickers, network performance measuring tools (e.g., network monitoring and traffic management applications), clickstream analysis tools, automobile traffic monitoring, and the like.

Communications subsystem 424 may also be configured to output the structured and/or unstructured data feeds 426, event streams 428, event updates 430, and the like to one or more databases that may be in communication with one or more streaming data source computers coupled to computer system 400.

Due to the ever-changing nature of computers and networks, the description of computer system 400 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

What is claimed is:

1. An embedded inductor, comprising:
a substrate;
a first layer of magnetic film, disposed on a first side of the substrate;
a second layer of magnetic film, disposed on a second side of the substrate;
a dielectric layer disposed over each of the first and second layers of magnetic film comprising;
a first redistribution layer formed over the dielectric layer;
a second redistribution layer a formed over the dielectric layer; and
two or more through-substrate vias (TSVs) extending through the dielectric layer and the substrate from the first redistribution layer to the second redistribution layer.

2. The embedded inductor of claim 1, wherein the first and second layers of magnetic film comprises Cadmium Zinc Telluride (CZT).

3. The embedded inductor of claim 1, wherein the dielectric layer comprises at least one of polyimide, zirconium, silica, or hydrogensilsesquioxanes.

4. The embedded inductor of claim 1, wherein the two or more TSVs form windings of the embedded inductor.

5. The embedded inductor of claim 1, wherein the first and second layers of magnetic film comprises a thickness within a range of about 1 μm to about 3 μm, inclusive.

6. The embedded inductor of claim 1, wherein the redistribution layer comprises copper.

7. The embedded inductor of claim 1, wherein the two or more TSVs comprise copper.

8. A dual core embedded inductor, comprising:
a substrate;
a first layer of magnetic film, disposed on a first side of the substrate;
a second layer of magnetic film, disposed on a second side of the substrate;
a dielectric layer disposed over each of the first and second layers of magnetic film;
a first redistribution layer formed over the dielectric layer on the first surface of the substrate;
a second redistribution layer formed over the dielectric layer on the second surface of the substrate;
two or more TSVs extending through the dielectric layer and the substrate from the first redistribution layer to the second redistribution layer;
a second dielectric layer disposed over each of the first and second redistribution layers;
a third layer of magnetic film disposed on the second dielectric layer over at least a portion of the first redistribution layer; and
a fourth layer of magnetic film disposed on the second dielectric layer over at least a portion of the second redistribution layer.

9. The dual core embedded inductor of claim 8, wherein the first and second redistribution layers extend beyond the second dielectric layer.

10. The dual core embedded inductor of claim 8, wherein the embedded inductor is an integrated voltage regulator.

11. The dual core embedded inductor of claim 8, wherein the embedded inductor is a switching inductor.

12. The dual core embedded inductor of claim 8, wherein the two or more TSVs form a winding of a solenoidal inductor.

13. The dual core embedded inductor of claim 8, wherein the first and second layers of magnetic film are formed from a material with a ferromagnetic resonance frequency of about 1 GHz to about 2 GHz, inclusive.

14. A method of forming an inductor, comprising:
forming two or more TSVs in a substrate such that the TSVs reaches the first surface of the substrate;
forming a first layer of magnetic film on the first surface of the substrate between at least two of the TSVs;
forming a first dielectric layer on the first surface of the substrate and the first layer of magnetic film;
forming a first metal layer on the first dielectric layer, such that the metal vias extend through the first dielectric layer;
extending the TSVs such that the TSVs reach a second surface of the substrate, opposite the first surface;
forming a second layer of magnetic film on the second surface of the substrate and between at least two of the TSVs;
forming a second dielectric layer on the second surface of the substrate and the second layer of magnetic film; and
forming a second metal layer on the second dielectric layer.

15. The method of claim 14, further comprising:
forming a third dielectric layer on the first metal layer;
forming a third layer of magnetic film on the third dielectric layer;
forming a fourth dielectric layer on the second metal layer; and
forming a fourth layer of magnetic film on the second dielectric layer.

16. The method of claim 14, wherein the first metal layer and the second metal layer comprises a redistribution layer.

17. The method of claim 14, wherein the two or more TSVs are formed at least in part using an etching process.

18. The method of claim 14, wherein the first and second metal layers are formed via a sputtering process.

19. The method of claim 14, wherein the substrate comprises silicon.

20. The method of claim 14, wherein first, second, third, and fourth layers of magnetic film are formed using a deposition process.
